(19) United States
(12) Patent Application Publication
(10) Pub. No.: US 2024/0392191 A1
(43) Pub. Date: Nov. 28, 2024

(54) ETCHING GAS COMPOSITION AND METHOD OF MANUFACTURING INTEGRATED CIRCUIT DEVICE USING THE SAME

(71) Applicant: SEMES CO., LTD., Chungcheongnam-do (KR)

(72) Inventors: Kyungseok MIN, Suwon-si (KR); Youngmoon KIM, Hwaseong-si (KR); Sooryun RO, Suwon-si (KR); Jisoo OH, Suwon-si (KR); Kwangbae KIM, Seoul-si (KR); Chulhee LEE, Osan-si (KR)

(21) Appl. No.: 18/670,706

(22) Filed: May 21, 2024

(30) Foreign Application Priority Data
May 25, 2023 (KR) 10-2023-0067663

(51) Int. Cl. C09K 13/00; H01L 21/02; H01L 21/311

(52) U.S. Cl. CPC C09K 13/00; H01L 21/31116; H01L 21/31144; H01L 21/02164; H01L 21/0217

(57) ABSTRACT

An etching gas composition includes an organic fluorine compound and carbon disulfide.

### CROSS-REFERENCE TO RELATED APPLICATION

This application is based on and claims priority under 35 U.S.C. § 119 to Korean Patent Application No. 10-2023-0067663, filed on May 25, 2023, in the Korean Intellectual Property Office, the disclosure of which is incorporated by reference herein in its entirety.

### BACKGROUND

### 1. Field

The disclosure relates to an etching gas composition and a method of manufacturing an integrated circuit device by using the same.

### 2. Description of the Related Art

With the development of the electronic industry, the degree of integration of semiconductor devices has increased, and accordingly, miniaturization of pattern sizes is needed. When the pattern sizes are miniaturized, patterns are distorted or pattern profiles are nonuniform. Accordingly, research on etching gas compositions having high etch selectivity and capable of implementing uniform pattern profiles has been conducted.

### SUMMARY

Provided is an etching gas composition having high etch selectivity and capable of implementing a uniform pattern profile.

Provided is a method of manufacturing an integrated circuit device having improved reliability.

Additional aspects will be set forth in part in the description which follows and, in part, will be apparent from the description, or may be learned by practice of the presented embodiments of the disclosure.

According to an aspect of the disclosure, an etching gas composition includes an organic fluorine compound and carbon disulfide.

A content of the carbon disulfide with respect to 100 parts by volume of the organic fluorine compound may be 2 parts by volume or less.

The organic fluorine compound may include aliphatic hydrocarbon having 3 to 10 carbon atoms, in which at least one of hydrogen atoms bonded to carbon is replaced with a fluorine atom.

The organic fluorine compound may include at least one selected from among an organic fluorine compound of a first group having 3 carbon atoms and an organic fluorine compound of a second group having 4 carbon atoms.

The organic fluorine compound of the first group may include at least two isomers.

The organic fluorine compound of the first group may include at least one selected from among 1,1,1,3,3,3-hexafluoropropane, 1,1,1,2,3,3-hexafluoropropane, and 1,1,2,2,3,3-hexafluoropropane.

The organic fluorine compound of the second group may include at least two isomers.

The organic fluorine compound of the second group may include at least one selected from among hexafluoroisobutene, 2,3,3,4,4,4-hexafluoro-1-butene, 1,1,1,4,4,4-hexafluoro-2-butene, (2Z)-1,1,1,4,4,4-hexafluoro-2-butene, (2Z)-1,1,1,2,4,4-hexafluoro-2-butene, 1,1,2,3,4,4-hexafluoro-2-butene, (2Z)-1,1,2,3,4,4-hexafluoro-2-butene, 1,1,2,2,3,3-hexafluorocyclobutane, and (3R, 4S)-1,1,2,2,3,4-hexafluorocyclobutane.

The etching gas composition may further include an inert gas and a reactive gas.

The inert gas may include at least one selected from among argon (Ar), helium (He), neon (Ne), nitrogen (N₂), krypton (Kr), and xenon (Xe), and the reactive gas may include at least one selected from among oxygen (O₂), ozone (O₃), carbon monoxide (CO), carbon dioxide (CO₂), carbonylchloride (COCl₂), carbonylfluoride (COF₂), nitrogen monoxide (NO), nitrogen dioxide (NO₂), and ammonia (NH₃).

According to another aspect of the disclosure, an etching gas composition includes an organic fluorine compound including aliphatic hydrocarbon having 3 to 10 carbon atoms, in which at least one of hydrogen atoms bonded to carbon is replaced with a fluorine atom, carbon disulfide, an inert gas, and a reactive gas.

A content of the carbon disulfide with respect to 100 parts by volume of the organic fluorine compound may be 0.01 parts by volume to 2 parts by volume.

The organic fluorine compound may include at least one selected from among CF₄, C₂F₆, C₃F₆, C₄F₆, C₄F₈, C₅F₈, and C₆F₆.

The organic fluorine compound may include at least one selected from among 1,1,2,2,3,3-hexafluoropropane, 1,1,1,2,3,3-hexafluoropropane, and 1,1,2,2,3,3-hexafluoropropane.

The organic fluorine compound may include at least one selected from among (3R, 4S)-1,1,2,2,3,4-hexafluorocyclobutane, hexafluoroisobutene, and (2Z)-1,1,1,4,4,4-hexafluoro-2-butene.

According to another aspect of the disclosure, a method of manufacturing an integrated circuit device includes alternately stacking a plurality of insulating layers and a plurality of sacrificial layers one by one on a substrate, forming a stepped structure by removing one end of each of the plurality of insulating layers and the plurality of sacrificial layers, forming an insulating block covering the stepped structure, replacing the plurality of sacrificial layers with a plurality of gate stacks, forming an insulating layer on the insulating block, forming an etching mask on the insulating layer, forming a contact hole by etching the insulating block and the insulating layer through the etching mask by using plasma obtained from an etching gas composition, and removing the etching mask, wherein the etching gas composition includes an organic fluorine compound and carbon disulfide.

The etching mask may include at least one selected from among photoresist (PR), a spin on hardmask (SOH), and an amorphous carbon layer (ACL).

Each of the insulating block and the insulating layer may include at least one of silicon nitride and silicon oxide.

A plasma source for obtaining the plasma may include any one of high frequency inductively coupled plasma (ICP) and capacitively coupled plasma (CCP).

A content of the carbon disulfide with respect to 100 parts by volume of the organic fluorine compound may be 2 parts by volume or less.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a plan view illustrating a hole shape of each of an upper end portion and a lower end portion of a layer to be etched, in which a vertical hole is formed by using an etching composition, according to embodiments;

FIG. 2 is a plan view illustrating a hole shape of each of an upper end portion and a lower end portion of a layer to be etched, in which a vertical hole is formed by using an etching composition, according to a comparative example;

FIG. 3 is a graph illustrating a change in an etch rate of each of silicon oxide and an amorphous carbon layer (hereinafter, as ACL) according to a content of carbon disulfide;

FIG. 4 is a graph illustrating a change in a thickness of an ACL on a layer to be etched according to a content of carbon disulfide; and

FIGS. 5 to 10 are cross-sectional views illustrating a method of manufacturing an integrated circuit device in a process sequence, according to embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

Hereinafter, embodiments are described in detail with reference to the accompanying drawings. The same reference numerals are used for the same components in the drawings, and the same descriptions thereof are omitted.

An etching gas composition according to embodiments may include an organic fluorine compound and carbon disulfide (CS₂).

In some embodiments, the organic fluorine compound may include aliphatic hydrocarbon having 3 to 10 carbon atoms, in which at least one of hydrogen atoms bonded to carbon is replaced with a fluorine atom. For example, the aliphatic hydrocarbon may include a linear chain, a branched chain, and a cyclic type.

In some embodiments, the organic fluorine compound may include a fluorocarbon compound. The organic fluorine compound may include a fluorocarbon compound having 1 to 10 carbon atoms. For example, the organic fluorine compound may include CF₄, C₂F₆, C₃F₆, C₄F₆, C₄F₈, C₅F₈, C₆F₆, or a combination thereof.

In some embodiments, the organic fluorine compound may include at least one selected from among a fluorinated hydrocarbon compound of a first group having 3 carbon atoms and a fluorinated hydrocarbon compound of a second group having 4 carbon atoms.

In some embodiments, an organic fluorine compound of the first group may include a fluorinated hydrocarbon compound having a chemical formula of C₃H₂F₆. For example, the organic fluorine compound of the first group may include 1,1,1,3,3-hexafluoropropane, 1,1,1,2,3,3-hexafluoropropane, and 1,1,2,2,3,3-hexafluoropropane.

In some embodiments, the organic fluorine compound may include at least two isomers selected from the group consisting of 1,1,1,3,3,3-hexafluoropropane, 1,1,1,2,3,3-hexafluoropropane, and 1,1,2,2,3,3-hexafluoropropane.

In some embodiments, an organic fluorine compound of the second group may include a fluorinated hydrocarbon compound having a chemical formula of C₄H₂F₆. For example, the organic fluorine compound of the second group may include hexafluoroisobutene, 2,3,3,4,4,4-hexafluoro-1-butene, 1,1,1,4,4,4-hexafluoro-2-butene, (2Z)-1,1,1,4,4,4-hexafluoro-2-butene, (2Z)-1,1,1,2,4,4-hexafluoro-2-butene, 1,1,2,3,4,4-hexafluoro-2-butene, (2Z)-1,1,2,3,4,4-hexafluoro-2-butene, 1,1,2,2,3,3-hexafluorocyclobutane, and (3R, 4S)-1,1,2,2,3,4-hexafluorocyclobutane.

In some embodiments, the organic fluorine compound may include at least two isomers selected from the group consisting of hexafluoroisobutene, 2,3,3,4,4,4-hexafluoro-1-butene, 1,1,1,4,4,4-hexafluoro-2-butene, (2Z)-1,1,1,4,4,4-hexafluoro-2-butene, (2Z)-1,1,1,2,4,4-hexafluoro-2-butene, 1,1,2,3,4,4-hexafluoro-2-butene, (2Z)-1,1,2,3,4,4-hexafluoro-2-butene, 1,1,2,2,3,3-hexafluorocyclobutane, and (3R, 4S)-1,1,2,2,3,4-hexafluorocyclobutane.

In some embodiments, a content of the organic fluorine compound with respect to 100 parts by volume of the etching gas composition may be about 0.01 parts by volume to about 98 parts by volume. In some embodiments, the content of the organic fluorine compound with respect to 100 parts by volume of the etching gas composition may be about 5 parts by volume to about 90 parts by volume, about 10 parts by volume to about 80 parts by volume, about 20 parts by volume to about 70 parts by volume, or about 30 parts by volume to about 70 parts by volume.

When an etching gas composition according to embodiments includes an organic fluorine compound and carbon disulfide together to form a vertical hole by using an etching mask on a layer to be etched, fluorinated carbon-based polymer may be formed on an inner wall of the vertical hole and the etching mask during an etching process. The fluorinated carbon-based polymer may form a passivation layer covering the etching mask and the inner wall of the vertical hole. Carbon disulfide may induce a passivation layer covering the inner wall of the vertical hole to be formed thicker, and thus, a profile of the vertical hole may be improved. For example, line edge roughness (LER) and line width roughness (LWR) of the vertical hole may be improved due to the passivation layer, and a bowing phenomenon may be prevented in which a diameter of the vertical hole extends and decreases according to an extension direction of the vertical hole (e.g., a vertical direction).

The etching mask may be at least one selected from among photoresist (PR), a spin on hardmask (SOH), and an amorphous carbon layer (ACL). The layer to be etched may include silicon nitride, silicon oxide, or a combination thereof. An etching mask according to embodiments may include a carbon-based material, and thus, fluorinated carbon-based polymer may be easily formed on a surface of the etching mask in an etching process.

In some embodiments, a content of the carbon disulfide with respect to 100 parts by volume of the organic fluorine compound may be 0.01 parts by volume to 2 parts by volume. In some embodiments, the content of the carbon disulfide with respect to 100 parts by volume of the organic fluorine compound may be 0.1 parts by volume to 2 parts by volume. When the content of the carbon disulfide is less than 0.1, fluorinated carbon-based polymer may not be sufficiently formed on the etching mask, and thus, the difference between the diameters of the upper end and the lower end of the vertical hole may increase. When the content of the carbon disulfide exceeds 2, an etch rate with respect to a layer to be etched may be reduced, and a hole pattern entrance of the etching mask may be clogged with fluorinated carbon-based polymer, and thus, a vertical hole pattern having a high aspect ratio may not be easily formed.

In some embodiments, the organic fluorine compound may include together a first component capable of improving an etch rate with respect to a layer to be etched, and a second component inducing formation of fluorinated carbon-based polymer on the layer to be etched.

In some embodiments, the first component may include 1,1,1,2,3,3-hexafluoropropane and 1,1,2,2,3,3-hexafluoropropane from among the organic fluorine compound of the first group. The first component may include hexafluoroisobutene and (2Z)-1,1,1,4,4,4-hexafluoro-2-butene from among the organic fluorine compound of the second group.

In some embodiments, the second component may include 1,1,2,2,3,3-hexafluoropropane from among the organic fluorine compound of the first group. The second component may include (3R, 4S)-1,1,2,2,3,4-hexafluorocyclobutane from among the organic fluorine compound of the second group.

In some embodiments, a volumetric content of the first component is larger than a volumetric content of the second component. In some embodiments, a volume ratio between the first component and the second component of the organic fluorine compound may be 3:1 to 19:1.

An organic fluorine compound of an etching gas composition according to embodiments may include the first component and the second component together, and accordingly, LER or LWR of each of an etching mask and a vertical hole may be reduced while improving etch selectivity and an etch rate of a layer to be etched/the etching mask. For example, by increasing the content of the carbon disulfide within the etching gas composition, a content of the first component of the organic fluorine compound may be increased to prevent clogging by the fluorinated carbon-based polymer. For example, by reducing the content of the carbon disulfide within the etching gas composition, a content of the second component of the organic fluorine compound may be increased to prevent over-etching of the etching mask.

According to embodiments, the etching gas composition may further include at least one of an inert gas and a reactive gas.

In some embodiments, the inert gas may include argon (Ar), helium (He), neon (Ne), nitrogen (N₂), krypton (Kr), xenon (Xe), or a mixture thereof. In some embodiments, a content of the inert gas with respect to 100 parts by volume of the organic fluorine compound may be about 10 parts by volume to about 10,000 parts by volume. In some embodiments, the content of the inert gas with respect to 100 parts by volume of the organic fluorine compound may be about 50 parts by volume to about 1,000 parts by volume.

In some embodiments, the reactive gas may include oxygen (O₂), ozone (O₃), carbon monoxide (CO), carbon dioxide (CO₂), carbonyl chloride (COCl₂), carbonyl fluoride (COF₂), nitrogen monoxide (NO), nitrogen dioxide (NO₂), nitrous oxide (N₂O), hydrogen (H₂), ammonia (NH₃), hydrogen fluoride (HF), sulfur dioxide (SO₂), carbonyl sulfide (COS), CF₃I, C₂F₃I, C₂F₅I, or a mixture thereof. In some embodiments, a content of the reactive gas with respect to 100 parts by volume of the organic fluorine compound may be about 0.1 parts by volume to about 5,000 parts by volume. In some embodiments, the content of the reactive gas with respect to 100 parts by volume of the organic fluorine compound may be about 1 part by volume to about 1,000 parts by volume.

The etching gas composition described above may include a silicon compound (e.g., silicon oxide and/or silicon nitride) having high etch selectivity with respect to an ACL. In particular, SiO₂/ACL and Si₃N₄/ACL may have high etch selectivity, and thus may be used to etch a channel hole and to form cell metal contact (CMC), a through via (THV), and the like.

Hereinafter, to help the understanding of the disclosure, experimental examples including detailed embodiments and comparative examples are provided, but only illustrate the disclosure and the disclosure is not limited to the following embodiments.

### Experimental Example 1—Evaluation of Diameter Deviation of Vertical Hole and Evaluation of Distortion of Vertical Hole

After sequentially stacking a layer to be etched (SiO₂) (3,000 nm) and a hole mask pattern (ACL) (300 nm) on a metal substrate, a channel hole, which exposes an upper surface of the metal substrate, is formed by using an etching gas composition having a composition according to Table 1 below. At each of a lower end portion (a point at which an upper surface of a substrate is exposed) and an upper end portion (a point 2,250 nm away from the upper surface of the substrate in a vertical direction) of a layer to be etched, a difference between the maximum diameter and the minimum diameter, and the maximum diameter of the upper end portion/a difference between the maximum diameter and a bowing diameter are measured with respect to each vertical hole and shown in Table 2 below.

TABLE 1

| | C₄F₈ | C₄F₆ | CS₂ | Ar | O₂ | Power | P | time |
|---|---|---|---|---|---|---|---|---|
| | Sccm | | | | | W/MHz | mTorr | min |
| Embodiment 1 | 65 | 35 | 2 | 300 | 60 | 600/100 | 20 | 10 |
| Comparative | 65 | 35 | 0 | 300 | 60 | 600/100 | 20 | 10 |
| Example 1 | | | | | | | | |

TABLE 2

| | | | Difference Between |
|---|---|---|---|
| | | | Maximum Diameter of |
| | | | Upper End portion of |
| | | | Vertical Hole and Bowing |
| | | | Diameter/Difference |
| | | | between Minimum |
| | Difference in | Difference in | Diameter of Lower End |
| | Diameter of Upper | Diameter of Lower | Portion of Vertical Hole |
| | End Portion of | End Portion of | and Bowing Diameter |
| | Vertical Hole (nm) | Vertical Hole (nm) | (nm) |
| Embodiment 1 | 14.2 | 55.2 | 0.6/13.6 |
| Comparative | 27.2 | 62.2 | 11.3/15.9 |
| Example 1 | | | |

Referring to Table 1, an etching gas composition according to Embodiment 1 includes 082, and thus, from a relative perspective, a difference between the maximum diameter and the minimum diameter of each of an upper end portion and a lower end portion is relatively reduced compared to Comparative Example 1 that does not include 082. From a relative perspective, the difference between the diameter of the upper end of the vertical hole and the bowing diameter is smaller in Embodiment 1 than in Comparative Example 1.

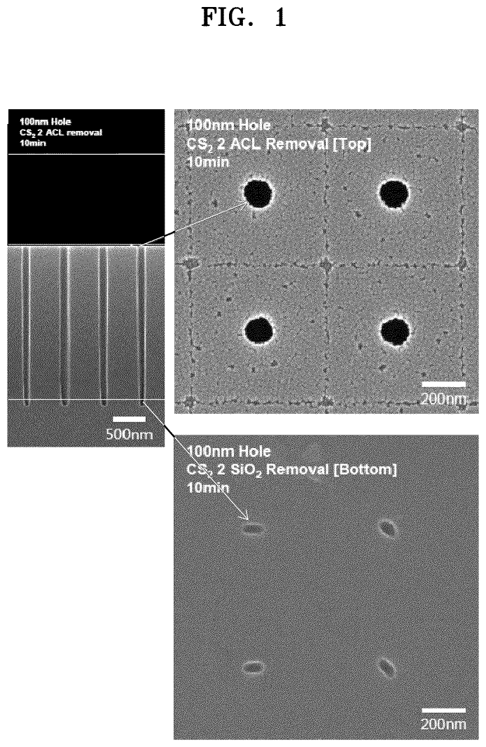

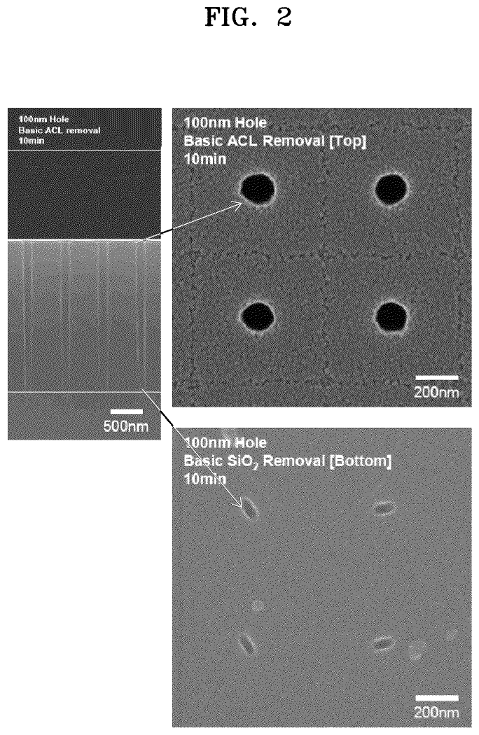

FIG. 1 is a plan view illustrating a shape of a vertical hole at each of an upper end portion and a lower end portion of a layer to be etched, according to Embodiment 1, and FIG. 2 is a plan view illustrating a shape of a vertical hole at each of an upper end portion and a lower end portion of a layer to be etched, according to Comparative Example 1.

Referring to FIGS. 1 and 2, in both Embodiment 1 and Comparative Example 1, distortion of the vertical hole appears at a lower end portion of the layer to be etched, and the vertical hole has a similar cross-sectional shape to an ellipse. However, from a relative perspective, the difference between the maximum diameter and the minimum diameter of the vertical hole at the lower end portion is more improved in Embodiment 1 including CS₂ than in Comparative Example 1.

### Experimental Example 2—Evaluation of Changes in Etch Rate of Layer to be Etched/Etching Mask and Thickness of ACL

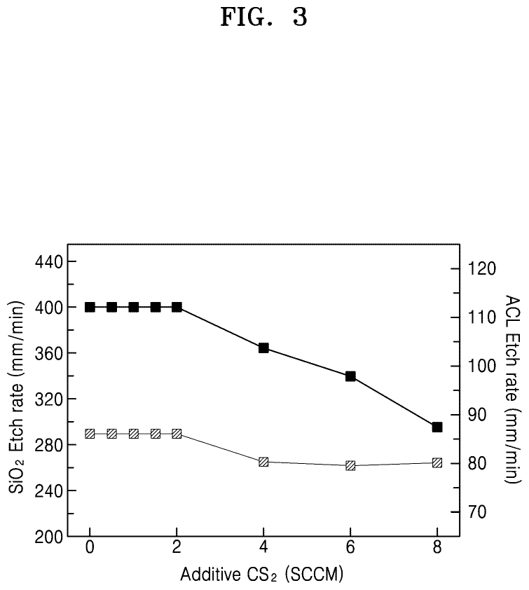

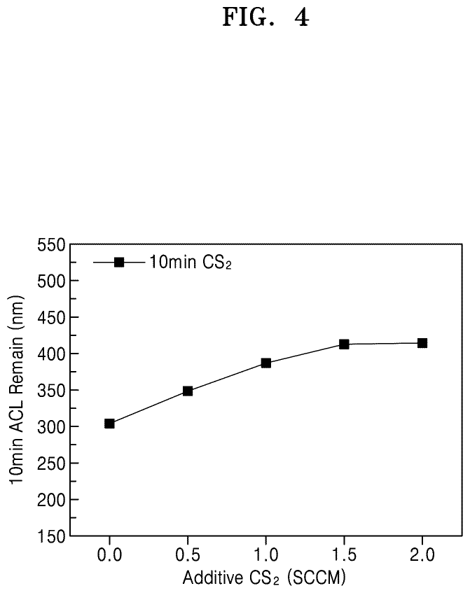

FIG. 3 is a graph illustrating a change in an etch rate of each of silicon oxide and an ACL according to a content of carbon disulfide, and FIG. 4 is a graph illustrating a change in a thickness of an ACL on a layer to be etched according to a content of carbon disulfide.

In detail, FIG. 3 illustrates that an etch rate of SiO₂ and an etch rate of an ACL are measured while varying the content of CS₂ in the same experimental condition as in Table 1, and FIG. 4 illustrates a change in a thickness of an etching mask (ACL) at an upper end of a layer to be etched with a change in the content of CS₂ in the same experimental condition as in Table 1.

Referring to FIG. 3, the etch rate is significantly reduced within a range in which the content of CS₂ exceeds 2 sccm. Referring to FIG. 4, the etching mask may is clogged with fluorinated carbon-based polymer with an increase in the content of CS₂, and thus, the thickness of the etching mask is increased. An amount of fluorinated carbon-based polymer deposited around the etching mask and an entrance of the vertical hole may increase with an increase in the content of CS₂. However, the etch rate of the layer to be etched decreases when the content of CS₂ exceeds 2 parts by volume with respect to 100 parts by volume of an organic fluorine compound. Accordingly, when a vertical hole is formed in a condition in which a content of CS₂ exceeds 2 parts by volume with respect to 100 parts by volume of an organic fluorine compound, a deposition rate of fluorinated carbon-based polymer may be greater than an etch rate of a layer to be etched. Therefore, an entrance of an etching mask for forming the vertical hole may be cogged with the fluorinated carbon-based polymer, and thus, the vertical hole having a high aspect ratio may not be easily formed.

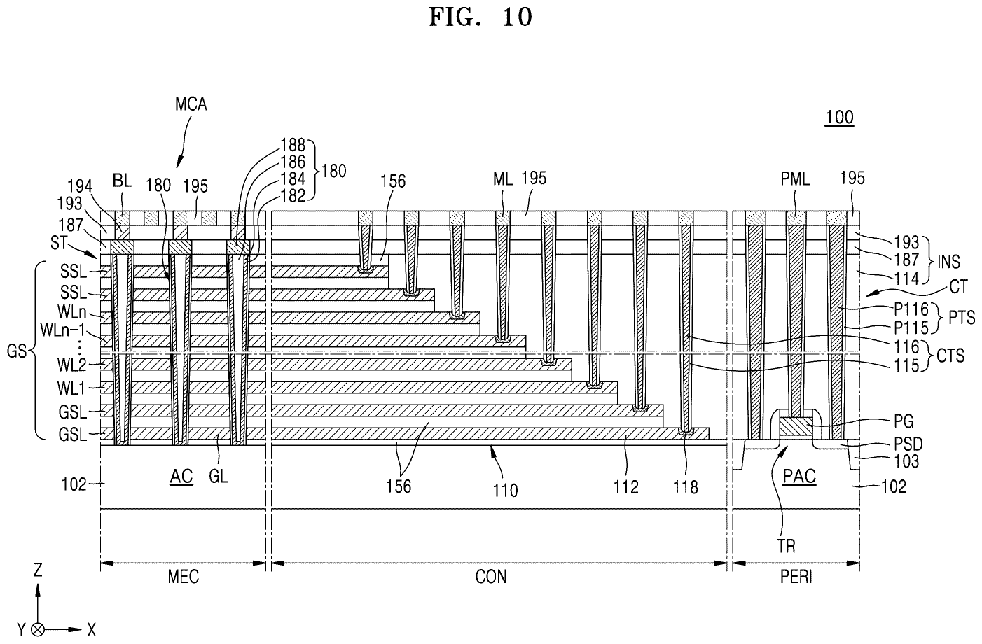

Hereinafter, a method of manufacturing an integrated circuit device 100 (refer to FIG. 10) by using an etching gas composition, according to the disclosure, is described by using a detailed example.

According to embodiments, the integrated circuit device 100 may be a semiconductor device including a vertical memory device including memory cells that are three-dimensionally arranged. According to embodiments, the integrated circuit device 100 may include a memory cell array including a plurality of memory cell blocks, and the plurality of memory cell blocks may be connected to a peripheral circuit through a bit line, a gate stack, a string select line, and a ground select line. The peripheral circuit may include a row decoder, a page buffer, a data input/output circuit, a control logic, and a common source line (CSL) driver. The peripheral circuit may further include various types of circuits such as a voltage generation circuit for generating various types of voltages needed for an operation of the integrated circuit device 100, an error correction circuit for correcting an error in data read from a memory cell array, and an input/output interface.

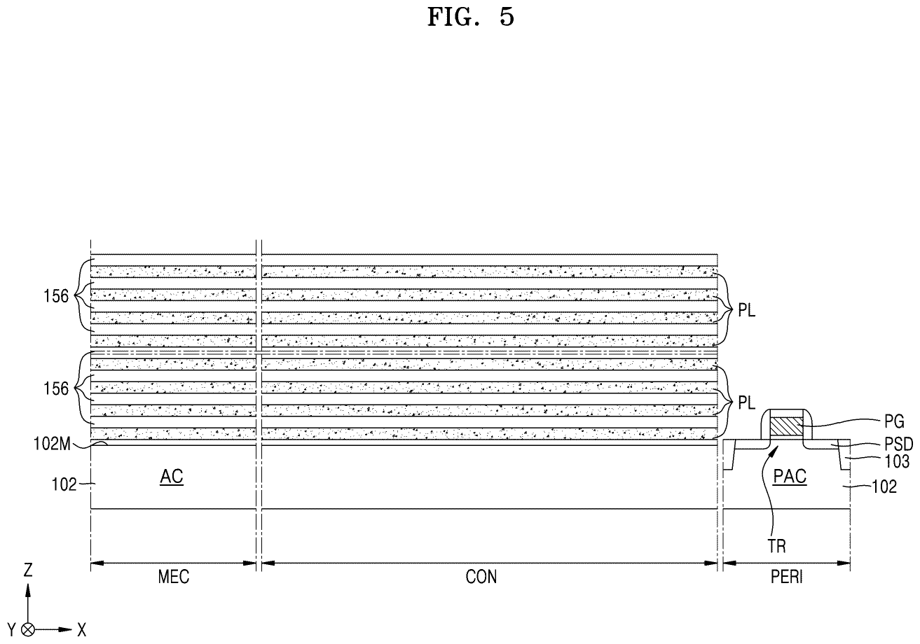

FIGS. 5 to 10 are cross-sectional views illustrating a method of manufacturing the integrated circuit device 100 in a process sequence, according to embodiments.

Referring to FIG. 5, a substrate 102 may have a memory cell region MEC, a connection region CON, and a peripheral circuit region PERI. According to embodiments, an active region AC may be defined in the memory cell region MEC of the substrate 102, and a peripheral active region PAC may be defined in the peripheral circuit region PERI.

According to embodiments, the peripheral active region PAC may be defined by a device isolation layer 103. For example, a memory cell array (MCA) may be formed on the active region AC of the memory cell region MEC, according to processes of manufacturing the integrated circuit device 100 (refer to FIG. 10) described below. For example, the connection region CON may be arranged adjacent to an edge side of the memory cell region MEC. The memory cell region MEC may be spaced apart from the peripheral circuit region PERI with the connection region CON therebetween. Although FIG. 5 illustrates only the connection region CON arranged on one side of the memory cell region MEC, connection regions CON may be respectively arranged on both sides of the memory cell region MEC in a first horizontal direction (i.e., an X direction).

According to embodiments, the device isolation layer 103, which defines the peripheral active region PAC, may be formed in the peripheral circuit region PERI of the substrate 102. A peripheral transistor TR may be formed on the peripheral active region PAC. The peripheral transistor TR may constitute a portion of a plurality of circuits formed on the peripheral circuit region PERI. The peripheral transistor TR may be configured to be electrically connected to the memory cell region MEC through a wiring structure arranged in the connection region COM. The peripheral transistor TR may include a peripheral gate PG and peripheral source/drain regions PSD formed within the peripheral active region PAC on both sides of the peripheral gate PG. In embodiments, unit devices such as a resistor and a capacitor may be further arranged on the peripheral circuit region PERI.

According to embodiments, the substrate 120 may have a main surface 102M extending in a horizontal direction along an X-Y plane. According to embodiments, the substrate 102 may include Si, Ge, or SiGe.

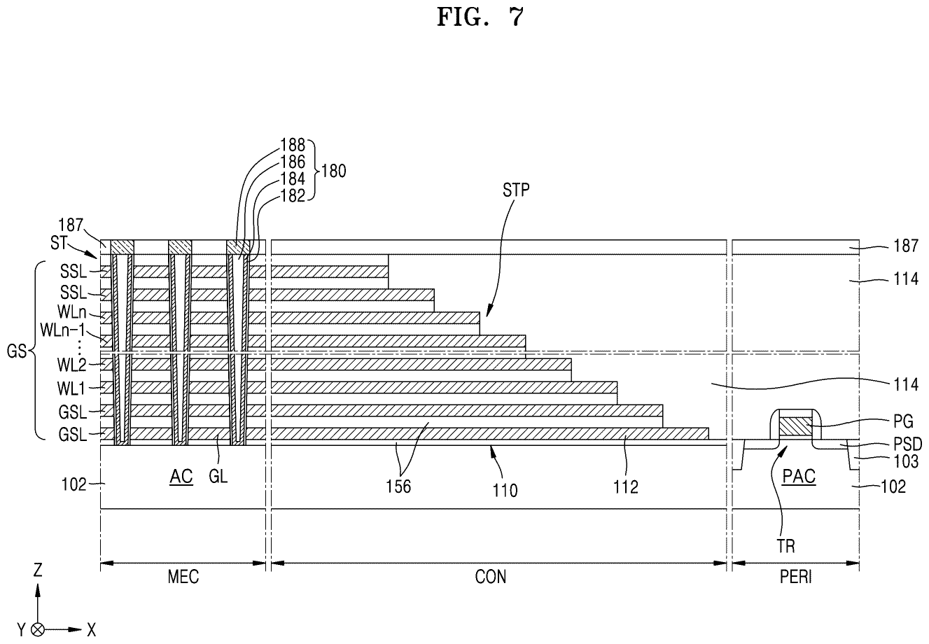

According to embodiments, a plurality of insulating layers 156 and a plurality of sacrificial layers PL may be alternately stacked one layer by one layer on the memory cell region MEC and the connection region CON of the substrate 102. For example, from among the plurality of insulating layers 156 on the substrate 102, the insulating layer 156 closest to the substrate 102 may have a smaller thickness than the other insulating layers 156. According to embodiments, the plurality of insulating layers 156 may include silicon oxide, silicon nitride, or silicon oxynitride. According to embodiments, the plurality of sacrificial layers PL may include silicon nitride, silicon carbide, or polysilicon. For example, the plurality of insulating layers 156 may include silicon oxide, and the plurality of sacrificial layers PL may include silicon nitride. Each of the plurality of sacrificial layers PL may operate to secure a space for forming a gate stack GS (refer to FIG. 7) in a subsequent process.

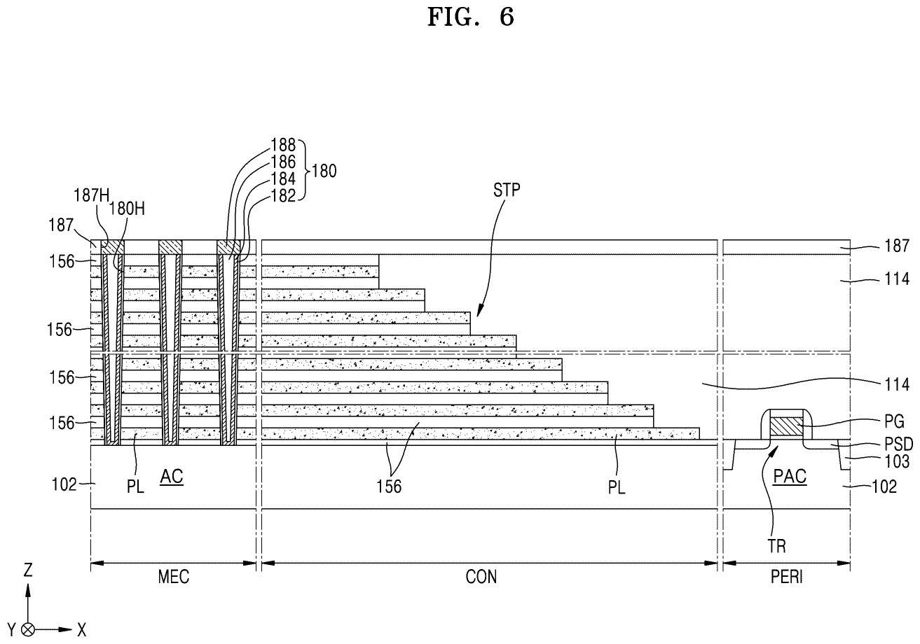

Referring to FIG. 6, in the resultant structure of FIG. 5, an etch stop layer (not shown), which covers the uppermost insulating layer 156 from among the plurality of insulating layers 156, may be formed, and then a portion of each of the plurality of insulating layers 156 and the plurality of sacrificial layers PL may be removed in the connection region CON by using a photolithography process to form a stepped structure STP having a width gradually decreasing in the horizontal direction as one end portion of each of the plurality of insulating layers 156 and the plurality of sacrificial layers PL is away from the substrate 102. Subsequently, an insulating block 114, which covers the stepped structure STP and the peripheral transistor TR, may be formed on the substrate 102.

Subsequently, in the memory cell region MEC, a plurality of channel holes 180H, which pass through the plurality of insulating layers 156 and the plurality of sacrificial layers PL and extend in a vertical direction (i.e., a Z direction), may be formed, and a plurality of channel hole buried structures may be formed by forming gate dielectric layers 182, channel regions 184, and buried insulating layers 186 inside the plurality of channel holes 180H, respectively. According to embodiments, the gate dielectric layers 182 may include silicon oxide, hafnium oxide, aluminum oxide, zirconium oxide, tantalum oxide, silicon nitride, boron nitride, silicon boron nitride, impurity-doped polysilicon, metal oxide, or a combination thereof. The metal oxide may include hafnium oxide, aluminum oxide, zirconium oxide, tantalum oxide, or a combination thereof. According to embodiments, the channel regions 184 may have a cylindrical shape. The channel regions 184 may include doped polysilicon or undoped polysilicon. According to embodiments, the buried insulating layers 186 may fill inner spaces of the channel regions 184. The buried insulating layers 186 may include an insulating material. For example, the buried insulating layers 186 may include silicon oxide, silicon nitride, silicon oxynitride, or a combination thereof. In some embodiments, the buried insulating layers 186 may be omitted, and in this case, the channel regions 184 may have pillar structures without inner spaces.

Subsequently, channel structures 180 may be formed by forming an intermediate insulating layer 187, which covers the plurality of channel hole buried structures, the stepped structure STP, and the insulating block 114, in the memory cell region MEC, the connection region CON, and the peripheral circuit region PERI, exposing upper surfaces of the plurality of channel hole buried structures by forming a plurality of contact holes 187H in the intermediate insulating layer 187, and forming a plurality of drain regions 188 within the plurality of contact holes 187H. The intermediate insulating layer 187 may be formed to have a planarized upper surface over the memory cell region MEC, the connection region CON, and the peripheral circuit region PERI. According to embodiments, the intermediate insulating layer 187 may include silicon oxide, silicon nitride, or silicon oxynitride. According to embodiments, the drain regions 188 may include doped polysilicon layers.

Referring to FIGS. 6 and 7 together, in the resultant structure of FIG. 6, the plurality of sacrificial layers PL may be replaced with a plurality of gate lines GL and a plurality of conductive pad regions 112.

Although not shown in FIGS. 6 and 7, in the resultant structure of FIG. 6, a plurality of word line cut trenches (not shown) may be formed to expose the substrate 102 by passing through the plurality of insulating layers 156 and the plurality of sacrificial layers PL. The plurality of word line cut trenches (not shown) may extend long in the first horizontal direction (i.e., the X direction), and may be formed to cross the memory cell region MEC and the connection region CON. For example, the cross-sections shown in FIGS. 5 and 6 may be vertical cross-sections of a region in the first horizontal direction (i.e., the X direction), which is spaced apart from the word line cut trenches (not shown) in a second horizontal direction (i.e., a Y direction).

According to embodiments, empty spaces may be provided between the plurality of insulating layers 156 by selectively removing the plurality of sacrificial layers PL (refer to FIG. 6) exposed through the plurality of word line cut trenches (not shown), and then a plurality of gate stacks GS may be formed by filling the empty spaces with a conductive material. According to embodiments, the plurality of gate stacks GS may include metal, metal silicide, impurity-doped semiconductor, or a combination thereof. For example, each of the plurality of gate stacks GS may include metal such as tungsten, nickel, cobalt, or tantalum, metal silicide such as tungsten silicide, nickel silicide, cobalt silicide, or tantalum silicide, doped polysilicon, or a combination thereof.

According to embodiments, the plurality of gate stacks GS may include the plurality of gate lines GL and the plurality of conductive pad regions 112 integrally connected to the plurality of gate lines GL. According to embodiments, the plurality of conductive pad regions 112 may constitute a stepped connection portion 110 on the connection region CON.

According to embodiments, a portion of the gate stack GS arranged on the memory cell region MEC may constitute a memory stack ST. For example, the memory stack ST may include 48, 64, 96, or 128 gate lines GL stacked in the vertical direction (the Z direction), but is not limited the above example. A plurality of gate lines GL included in the gate stack GS may be arranged on the memory cell region MEC, extend in the horizontal direction parallel to the main surface 102M of the substrate 102, and may overlap each other in the vertical direction (i.e., the Z direction). According to embodiments, the plurality of gate lines GL may include a plurality of word lines WL (WL1, WL2, . . . , WLn−1, and WLn), at least one ground select line GSL, and at least one string select line SSL. Although FIG. 7 illustrates a case where the plurality of gate lines GL include two ground select lines GSL and two string select lines SSL, the disclosure is not limited thereto.

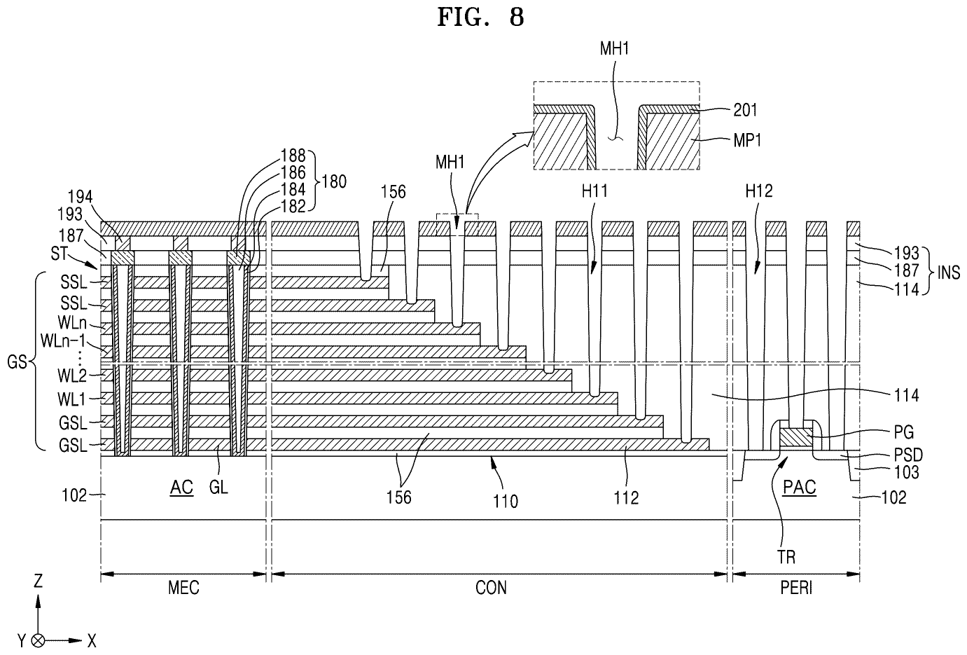

Referring to FIG. 8, after an upper insulating layer 193 is formed on the resultant structure of FIG. 7, a plurality of bit line contact pads 194, which pass through the upper insulating layer 193 and are connected to the plurality of channel structures 180, may be formed in the memory cell region MEC. The insulating block 114, the intermediate insulating layer 187, and the upper insulating layer 193 may constitute an insulating structure INS. According to embodiments, the plurality of bit line contact pads 194 may be insulated from each other by the upper insulating layer 193. The plurality of bit line contact pads 194 may include metal, metal nitride, or a combination thereof. According to embodiments, the upper insulating layer 193 may include an oxide layer, a nitride layer, or a combination thereof.

Subsequently, a mask pattern MP1 having a first opening MH1 may be formed on the upper insulating layer 193. According to embodiments, the mask pattern MP1 may be used as an etching mask, and in this case, the insulating structure INS may be a layer to be etched. For example, the mask pattern MP1 may be used as an etching mask for patterning the insulating structure INS.

According to embodiments, the mask pattern MP1 may be formed by sequentially forming a hard mask material layer (not shown) and a photoresist pattern (not shown) on the upper insulating layer 193, and then etching the hard mask material layer (not shown) by using the photoresist pattern (not shown) as an etching mask. In some embodiments, the photoresist pattern (not shown) may be formed through exposure and development after forming a photoresist material layer (not shown) without forming the hard mask material layer (not shown) on the upper insulating layer 193. In this case, the photoresist pattern may operate as the mask pattern MP1.

According to embodiments, the mask pattern MP1 may be a hard mask pattern. For example, the mask pattern MP1 may include an SOH, an ACL, or a combination thereof.

According to embodiments, by anisotropically etching the insulating structure INS on the connection region CON and the peripheral circuit region PERI by using the mask pattern MP1 as an etching mask, a plurality of first contact holes H11, which expose the plurality of conductive pad regions 112, may be formed on the connection region CON, and a plurality of second contact holes H12, which expose the peripheral gate PG and the peripheral source/drain regions PSD, may be formed on the peripheral circuit region PERI. In some embodiments, the first contact holes H11 and the second contact holes H12 may be sequentially formed. In some embodiments, the first contact holes H11 may be formed after forming the second contact holes H12. In some embodiments, the plurality of first contact holes H11 and the plurality of second contact holes H12 may be formed at the same time.

According to embodiments, to form the first contact holes H11 and the second contact holes H12, electrical bias may be applied to an etching gas composition according to embodiments while supplying the etching gas composition. For example, the etching gas composition may be converted into a plasma state and perform anisotropic etching by electrical bias.

According to embodiments, inductively coupled plasma (ICP) equipment or capacitively coupled plasma (CCP) equipment may be used as etching equipment using plasma. However, the disclosure is not limited thereto, and reactive ion etching (RIE) equipment, magnetically enhanced reactive ion etching (MERIE) equipment, transformer coupled plasma (TCP) equipment, hollow anode type plasma equipment, helical resonator plasma equipment, electronic cyclotron resonance (ECR) plasma equipment, or the like may be used.

According to embodiments, a passivation layer 201, which covers an upper surface of the mask pattern MP1 and an inner wall of the mask hole MH1, may be formed while an etching process is performed by the etching gas composition in a plasma state. For example, the passivation layer 201 may include fluorinated carbon-based polymer including C—C, C—F, and C—H bonds.

When an etching process is performed by using an etching gas composition according to embodiments, LER and LWR of the mask pattern MP1 and the insulating structure INS may be improved by forming the passivation layer 201 on the mask pattern MP1, and clogging due to excessive growth of the passivation layer 201 may be suppressed, and thus, high aspect ratio contact (HARC) having a high quality with reduced bowing or tapering may be formed.

According to embodiments, the anisotropic etching may be performed in a temperature range of about 250 K to about 420 K, about 260 K to about 400 K, about 270 K to about 380 K, about 280 K to about 360 K, or about 290 K to about 340 K.

Subsequently, the mask pattern MP1 may be removed by performing an ashing process under an oxygen (O₂)-containing atmosphere. In this case, the passivation layer 201 may be removed together.

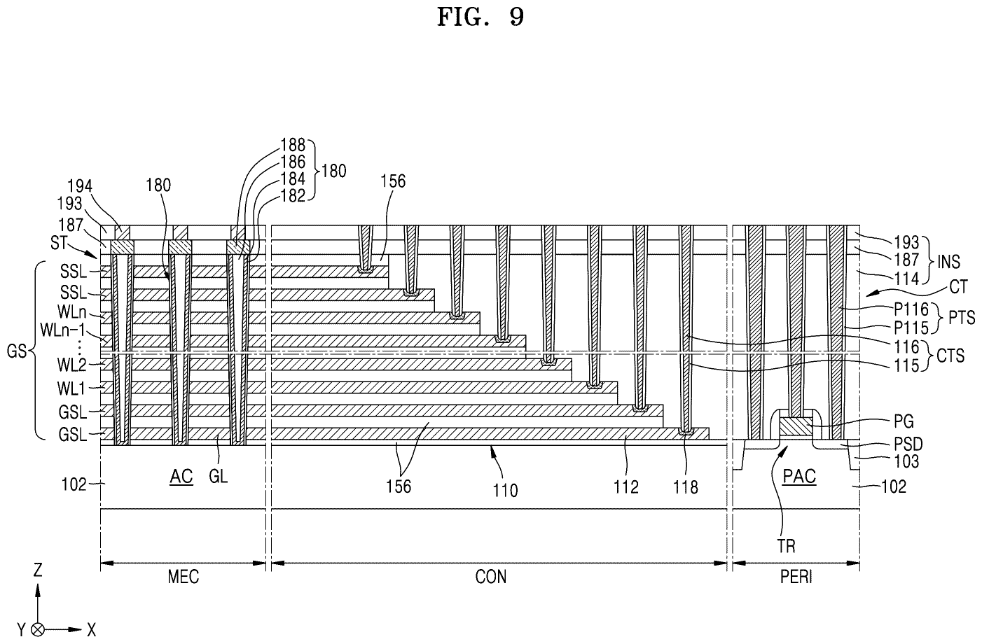

Referring to FIG. 9, on the connection region CON, a metal silicide layer 118 may be formed on a surface of the conductive pad region 112 exposed through each of the plurality of first contact holes H11, and a contact structure CTS may be formed on the metal silicide layer 118 inside each of the plurality of first contact holes H11. For example, the contact structure CTS may include a contact plug 116, which extends in the vertical direction (i.e., the Z direction) and contacts the metal silicide layer 118, and an insulating plug 115 surrounding the contact plug 116. Also, on the peripheral circuit region PERI, a peripheral contact structure (PTS) may be formed by sequentially forming peripheral insulating plugs P115 and peripheral contact plugs P116 inside the plurality of second contact holes H12. According to embodiments, each of the insulating plug 115 and the peripheral insulating plug P115 may include a silicon nitride layer, a silicon oxide layer, or a combination thereof. According to embodiments, each of the contact plug 116 and the peripheral contact plug P116 may include tungsten, titanium, tantalum, copper, aluminum, titanium nitride, tantalum nitride, tungsten nitride, or a combination thereof. According to embodiments, the metal silicide layer 118 may include WSi, WSiN, WSiO, or a combination thereof. The terms “WSi,” “WSiN,” and “WSiO” used herein may refer to materials including elements included in the respective terms, and may not be chemical formulas representing stoichiometric relationships.

Referring to FIG. 10, on the memory cell region MEC, the connection region CON, and the peripheral circuit region PERI, an interlayer insulating layer 195 covering the resultant structure of FIG. 9 may be formed, and then a plurality of bit lines BL, a plurality of wiring layers ML, and a plurality of peripheral wiring layers PML, which pass through partial regions of the interlayer insulating layer 195, may be formed.

According to embodiments, the drain region 188 of each of the plurality of channel structures 180 may be connected to corresponding one bit line BL from among the plurality of bit lines BL through the bit line contact pad 194. According to embodiments, the plurality of bit lines BL may be insulated from each other by the interlayer insulating layer 195. According to embodiments, the plurality of bit lines BL may include metal, metal nitride, or a combination thereof. For example, the plurality of bit lines BL may include tungsten, titanium, tantalum, copper, aluminum, titanium nitride, tantalum nitride, tungsten nitride, or a combination thereof. According to embodiments, the interlayer insulating layer 195 may include an oxide layer, a nitride layer, or a combination thereof.

According to embodiments, the plurality of wiring layers ML may be formed at the same level as the plurality of bit lines BL arranged on the memory cell region MEC. According to embodiments, the plurality of wiring layers ML may be respectively connected to the contact plugs 116 of the contact structures CTS. According to embodiments, each of the plurality of wiring layers ML may be configured to be electrically connected to one conductive pad region 112 selected from among the plurality of conductive pad regions 112 through one contact plug 116 selected from among the plurality of contact plugs 116. According to embodiments, the plurality of wiring layers ML may not include portions vertically overlapping the memory stack ST. According to embodiments, on the connection region CON, the plurality of wiring layers ML may be insulated from each other by the interlayer insulating layer 195. According to embodiments, the plurality of wiring layers ML may include tungsten, titanium, tantalum, copper, aluminum, titanium nitride, tantalum nitride, tungsten nitride, or a combination thereof.

According to embodiments, the plurality of peripheral wiring layers PML may extend long in the horizontal direction at the same level as a level of the plurality of wiring layers ML formed in the connection region CON. According to embodiments, each of the plurality of peripheral wiring layers PML may be connected to any one of the peripheral gates PG and the peripheral source/drain regions PSD through any one of the plurality of peripheral contact plugs P116. At least some of the plurality of peripheral wiring layers PML may be configured to be connected to other circuits or wires arranged on the peripheral circuit region PERI. The plurality of peripheral wiring layers PML may be insulated from each other by the interlayer insulating layer 195. According to embodiments, each of the plurality of peripheral wiring layers PML may include tungsten, titanium, tantalum, copper, aluminum, titanium nitride, tantalum nitride, tungsten nitride, or a combination thereof.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

What is claimed is:

1. An etching gas composition comprising:
an organic fluorine compound; and
carbon disulfide.

2. The etching gas composition of claim 1, wherein a content of the carbon disulfide with respect to 100 parts by volume of the organic fluorine compound is 2 parts by volume or less.

3. The etching gas composition of claim 1, wherein the organic fluorine compound includes aliphatic hydrocarbon having 3 to 10 carbon atoms, in which at least one of hydrogen atoms bonded to carbon is replaced with a fluorine atom.

4. The etching gas composition of claim 1, wherein the organic fluorine compound includes at least one selected from among an organic fluorine compound of a first group having 3 carbon atoms and an organic fluorine compound of a second group having 4 carbon atoms.

5. The etching gas composition of claim 4, wherein the organic fluorine compound of the first group includes at least two isomers.

6. The etching gas composition of claim 4, wherein the organic fluorine compound of the first group includes at least one selected from among 1,1,1,3,3,3-hexafluoropropane, 1,1,1,2,3,3-hexafluoropropane, and 1,1,2,2,3,3-hexafluoropropane.

7. The etching gas composition of claim 4, wherein the organic fluorine compound of the second group includes at least two isomers.

8. The etching gas composition of claim 4, wherein the organic fluorine compound of the second group includes at least one selected from among hexafluoroisobutene, 2,3,3,4,4,4-hexafluoro-1-butene, 1,1,1,4,4,4-hexafluoro-2-butene, (2Z)-1,1,1,4,4,4-hexafluoro-2-butene, (2Z)-1,1,1,2,4,4-hexafluoro-2-butene, 1,1,2,3,4,4-hexafluoro-2-butene, (2Z)-1,1,2,3,4,4-hexafluoro-2-butene, 1,1,2,2,3,3-hexafluorocyclobutane, and (3R, 4S)-1,1,2,2,3,4-hexafluorocyclobutane.

9. The etching gas composition of claim 1, further comprising:
an inert gas; and
a reactive gas.

10. The etching gas composition of claim 9, wherein the inert gas includes at least one selected from among argon (Ar), helium (He), neon (Ne), nitrogen (N₂), krypton (Kr), and xenon (Xe), and the reactive gas includes at least one selected from among oxygen (O₂), ozone (O₃), carbon monoxide (CO), carbon dioxide (CO₂), carbonylchloride (COCl₂), carbonylfluoride (COF₂), nitrogen monoxide (NO), nitrogen dioxide (NO₂), and ammonia (NH₃).

11. An etching gas composition comprising:
an organic fluorine compound including aliphatic hydrocarbon having 3 to 10 carbon atoms, in which at least one of hydrogen atoms bonded to carbon is replaced with a fluorine atom;
carbon disulfide;
an inert gas; and
a reactive gas.

12. The etching gas composition of claim 11, wherein a content of the carbon disulfide with respect to 100 parts by volume of the organic fluorine compound is 0.01 parts by volume to 2 parts by volume.

13. The etching gas composition of claim 11, wherein the organic fluorine compound includes at least one selected from among CF₄, C₂F₆, C₃F₆, C₄F₆, C₄F₈, C₅F₈, and C₆F₆.

14. The etching gas composition of claim 11, wherein the organic fluorine compound includes at least one selected from among 1,1,2,2,3,3-hexafluoropropane, 1,1,1,2,3,3-hexafluoropropane, and 1,1,2,2,3,3-hexafluoropropane.

15. The etching gas composition of claim 11, wherein the organic fluorine compound includes at least one selected from among (3R, 4S)-1,1,2,2,3,4-hexafluorocyclobutane, hexafluoroisobutene, and (2Z)-1,1,1,4,4,4-hexafluoro-2-butene.

16. A method of manufacturing an integrated circuit device, the method comprising:
alternately stacking a plurality of insulating layers and a plurality of sacrificial layers one by one on a substrate;
forming a stepped structure by removing one end of each of the plurality of insulating layers and the plurality of sacrificial layers;
forming an insulating block covering the stepped structure;
replacing the plurality of sacrificial layers with a plurality of gate stacks;
forming an insulating layer on the insulating block;
forming an etching mask on the insulating layer;
forming a contact hole by etching the insulating block and the insulating layer through the etching mask by using plasma obtained from an etching gas composition; and
removing the etching mask, wherein the etching gas composition includes: an organic fluorine compound; and carbon disulfide.

17. The method of claim 16, wherein the etching mask includes at least one selected from among photoresist (PR), a spin on hardmask (SOH), and an amorphous carbon layer (ACL).

18. The method of claim 16, wherein each of the insulating block and the insulating layer includes at least one of silicon nitride and silicon oxide.

19. The method of claim 16, wherein a plasma source for obtaining the plasma includes any one of high frequency inductively coupled plasma (ICP) and capacitively coupled plasma (CCP).

20. The method of claim 16, wherein a content of the carbon disulfide with respect to 100 parts by volume of the organic fluorine compound is 2 parts by volume or less.
